(19) United States
(12) Patent Application Publication
(10) Pub. No.: US 2026/0136949 A1
(43) Pub. Date: May 14, 2026

(54) PACKAGE STRUCTURE

(71) Applicant: GIGADEVICE SEMICONDUCTOR INC., Haidian (CN)

(72) Inventors: Yong Du, Beijing (CN); Yang Liu, Beijing (CN); Yuanyuan Li, Beijing (CN)

(73) Assignee: GIGADEVICE SEMICONDUCTOR INC., Haidian (CN)

(21) Appl. No.: 19/384,142

(22) Filed: Nov. 10, 2025

(30) Foreign Application Priority Data
Nov. 12, 2024 (CN) 202411612852.6
Nov. 12, 2024 (CN) 202411613027.8
Mar. 25, 2025 (CN) 202510362047.0

(51) Int. Cl. H01L 23/495; H01L 23/00; H01L 25/065

(52) U.S. Cl. CPC H10W 70/421; H10W 70/411; H10W 90/00; H10W 90/756; H10W 90/811

(57) ABSTRACT

A package structure is provided. The package structure includes a lead frame comprising a paddle and a plurality of pins arranged around the paddle. Above the paddle are disposed at least one metallized structure and at least one die. The die has a plurality of power pads on its front side. The plurality of power pads are connected to the metallized structure by first bonding wires, and the metallized structure is connected to corresponding pins by second bonding wires.

### CROSS-REFERENCE TO RELATED APPLICATION

This application claims the priority of Chinese patent application number 202411612852.6, filed on Nov. 12, 2024, and entitled “PACKAGE STRUCTURE”; Chinese patent application number 202411613027.8, filed on Nov. 12, 2024, and entitled “PACKAGE STRUCTURE”; and Chinese patent application number 202510362047.0, filed on Mar. 25, 2025, and entitled “PACKAGE STRUCTURE”, the entire contents of which are incorporated herein by reference.

### TECHNICAL FIELD

The present invention relates to the field of packaging technology and, in particular, to a package structure.

### BACKGROUND

FIG. 1 shows a cross-sectional view of a conventional package structure. FIG. 2 shows a front view of the conventional package structure. As shown in FIGS. 1 and 2, the package structure includes a lead frame 10 and a die 20. The lead frame 10 includes a paddle 101 and a plurality of pins 102. The die 20 is attached to the paddle 101, with power pads 201 and signal input/output pads 202 on the die 20 being connected to corresponding pins 102 by bonding wires 30.

In this package structure, since the power pads 201 on the die 20 share pin resources with the signal input/output pads 202, their external connection is limited by the availability of pin resources. Referring to FIG. 2, only some of the power pads 201 can be externally connected to pins 102, while the remaining ones cannot (e.g., as indicated by the dashed box of FIG. 2). This is not conducive to electrostatic discharge (ESD) protection of the package structure.

Further, conventional dies, such as those for automotive use, are usually associated with multiple different power distribution networks (PDNs), which are mismatched in impedance, leading to low power transmission efficiency and insufficiently stable circuit performance, and operate at distinct voltages. Therefore, regular package structures are not suitable for use with multiple PDNs. In conventional multiple-PDN designs, impedance continuity of the PDNs is often increased by assigning more pins to power pads. This, however, means fewer pins available for general-purpose input/output GPIO pads.

### SUMMARY OF THE INVENTION

To this end, the present invention provides a package structure. The package structure comprises: a lead frame comprising a paddle and a plurality of pins arranged around the paddle; at least one metallized structure disposed above the paddle; and at least one die disposed above the paddle, wherein a plurality of power pads are provided on a front side of the die, wherein the plurality of power pads are connected to the metallized structure by first bonding wires, and wherein the metallized structure is connected to corresponding pins by second bonding wires.

### BRIEF DESCRIPTION OF THE DRAWINGS

FIG. 1 shows a cross-sectional view of a conventional package structure.

FIG. 2 shows a top view of the conventional package structure.

FIG. 3 is a cross-sectional view of a package structure according to a first embodiment of the present invention, showing a metallized structure underlying a die.

FIG. 4 is a schematic front view of the package structure according to the first embodiment of the present invention, showing the metallized structure underlying the die.

FIG. 5 shows a schematic cross-sectional view of a metal metallized structure in the first embodiment of the present invention.

FIG. 6 is a cross-sectional view of the package structure according to the first embodiment of the present invention, showing an RDL metallized structure therein.

FIG. 7 shows a schematic assembly view of the die and the RDL metallized structure in the first embodiment of the present invention.

FIG. 8 is a front view of the package structure according to the first embodiment of the present invention, showing ground pads on the die, which are connected to a paddle.

FIG. 9 is a cross-sectional view of the package structure according to the first embodiment of the present invention, showing a plurality of dies stacked on the metallized structure.

FIG. 10 is a cross-sectional view of a package structure according to a second embodiment of the present invention, showing a metallized structure located over a die.

FIG. 11 is a cross-sectional view of the package structure according to the second embodiment of the present invention, showing a metallized structure being interposed between multiple dies.

FIG. 12 is a cross-sectional view of the package structure according to the second embodiment of the present invention, showing a metallized structure being disposed above multiple dies.

FIG. 13 shows a schematic top view of a package structure according to a third embodiment of the present invention.

FIGS. 14 to 17 show schematic cross-sectional views of the package structure according to the third embodiment of the present invention.

FIG. 18 shows a schematic cross-sectional view of a QFN package according to an embodiment of the present invention.

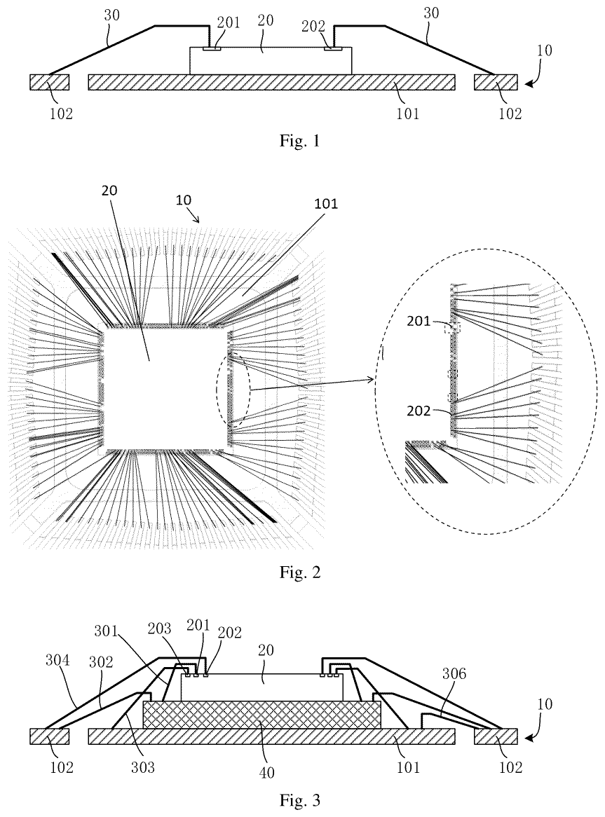

### REFERENCE NUMERALS

10 lead frame; 101 paddle; 102 pin; 20 die; 201 power pad; 202 signal input/output pad; 203 ground pad; 301 first bonding wire; 301a first portion of first bonding wires; 301b second portion of first bonding wires; 301c third portion of first bonding wires; 302 second bonding wire; 302a first portion of second bonding wires; 302b second portion of second bonding wires; 302c third portion of second bonding wires; 303 third bonding wire; 304 fourth bonding wire; 305 fifth bonding wire; 306 sixth bonding wire; 307 seventh bonding wire; 40 metallized structure; 40a first metallized structure; 40b second metallized structure; 40c third metallized structure; 401 silicon substrate; 402 metal layer; 403 RDL; 50 encapsulant.

### DETAILED DESCRIPTION

Herein, there is provided a package structure with enhanced ESD protection and higher power supply integrity. The package structure comprises a lead frame, a metallized structure and at least one die. The lead frame includes a paddle and a plurality of pins arranged around the paddle. The metallized structure and the die are stacked above the paddle, with a backside of the die facing toward the paddle and its front side facing away from the paddle. On the front side of the die, there is a plurality of power pads that are connected to the metallized structure by first bonding wires and metallized structure is connected to the corresponding pins by second bonding wires. With the presence of the metallized structure, the number of externally connectable power pads is not limited by the availability of pin resources, and the external connection of the power pads is not limited by their own location. Consequently, multiple power pads on the front side of the die, or even all of them, could be connected to the pins, allowing electrostatic charge to be preferentially discharged through a power supply (VDD) circuit. This imparts enhanced ESD protection and power supply integrity to the package structure, without retrofit of the die itself or of the lead frame in terms of design, increasing compatibility of the package structure.

Package structures proposed herein will be described in greater detail below with reference to the accompanying drawings, which illustrate specific embodiments of the present invention. From the following description, advantages and features of the present invention will be more apparent. Note that the figures are provided in a very simplified form not necessarily drawn to exact scale for the only purpose of helping explain the disclosed embodiments in a more convenient and clearer way.

### Embodiment 1

In some embodiments, a metallized structure may be attached to a paddle, with a die being in turn attached to the metallized structure.

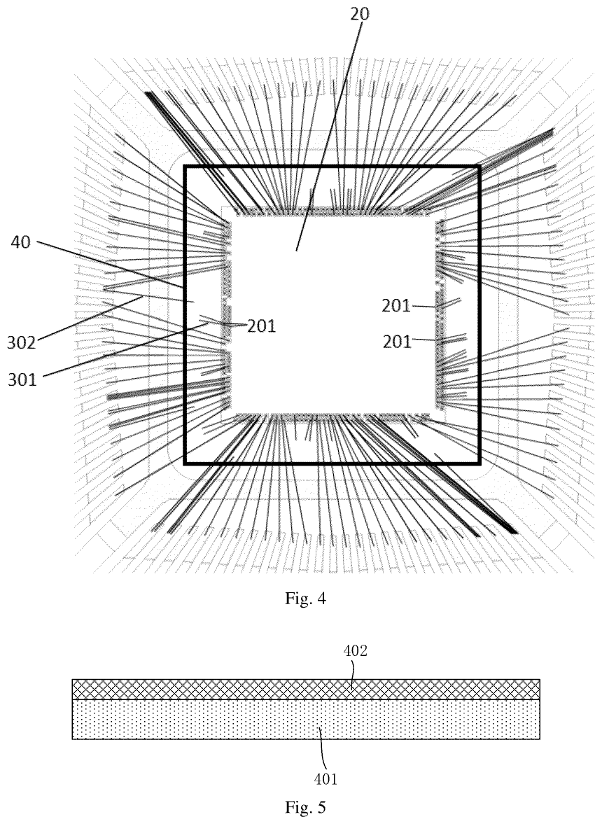

FIG. 3 is a cross-sectional view of a package structure according to an embodiment of the present invention, showing a metallized structure underlying a die, and FIG. 4 shows a schematic front view of the package structure in which a metallized structure underlies a die.

Referring to FIGS. 3 and 4, a package structure according to some embodiments includes a lead frame 10, a metallized structure 40 and at least one die 20. The lead frame 10 includes a paddle 101 and a plurality of pins 102 arranged around the paddle 101. The metallized structure 40 is attached to the paddle 101, and the die 20 is attached to the metallized structure 40, a backside of the die 20 faces toward the paddle 101 and a front side thereof faces away from the paddle 101. On the front side of the die 20, there is a plurality of power pads 201 that are connected to the metallized structure 40 by first bonding wires 201, and the metallized structure 40 is connected to the corresponding pins 102 by second bonding wires 302.

In this embodiment, the pins 102 of the lead frame 10 may be arranged to surround the periphery of the paddle 101 to facilitate connection of the metallized structure 40 and the die 20 on the paddle 101 to the pins 102.

For example, the metallized structure 40 and the die 20 are mounted to a front side of the paddle 101. In a non-limiting example, top surfaces of end portions of the pins 102 proximal to the paddle 101 may lie in the same plane as the front side of the paddle 101.

For example, the pin 102 may be made of a metal material, such as, for example, one or more of tungsten (W), aluminum (Al), copper (Cu), titanium (Ti), silver (Ag), gold (Au), platinum (Pt) and nickel (Ni). The paddle 101 may be made of the same material as the pin 102, or not. In some embodiments, the paddle 101 is made of a metal material or an insulating material. The metal material may be one or more of W, Al, Cu, Ti, Ag, Au, Pt and Ni, and the insulating material may be inorganic or organic. The inorganic insulating material may be one or more of silicon oxide, silicon nitride, silicon oxynitride and silicon oxycarbide. The organic insulating material may be an epoxy, polyimide, benzocyclobutene or polybenzoxazole resin. Alternatively, the organic insulating material may be polybutylene terephthalate, polycarbonate, polyethylene terephthalate, polyethylene, polypropylene, polyolefin, polyurethane, polyolefin, polyethersulfone, polyamide, polyurethane, poly(ethylene-vinyl acetate) or polyvinyl alcohol.

Referring to FIGS. 3 and 4, there is a plurality of pads on the front side of the die 20, which may include the plurality of power pads 201, a plurality of signal input/output pads 202 and a plurality of ground pads 203. These pads may be arranged in peripheral regions of the front side of the die. For example, in the case of the die 20 being rectangular in shape, the pads may be arranged alongside the four sides of the die 20.

It should be noted that although for ease of illustration, the power pads 201, the signal input/output pads 202 and the ground pads 203 have been depicted in the same cross-sectional plane in the annexed cross-sectional drawings, such as FIG. 3, they may not be actually located in the same cross-sectional plane in practice. Additionally, although multiple pins connected to bonding wires appear at the same locations in the annexed cross-sectional drawings, such as FIG. 3, in practice, bonding wires electrically connected to pads of different types are connected to different corresponding pins. For example, the second bonding wires 302 connected to the metallized structure 40, sixth bonding wires 306 connected to the paddle 101 and fourth bonding wires 304 connected to the signal input/output pads 202 are connected to different pins 102.

In this embodiment, the die 20 may be a non-encapsulated bare die, without limitation.

Referring to FIG. 3, in this embodiment, a backside of metallized structure 40 is attached to the front side of the paddle 101, and the backside of the die 20 is attached to a front side of the metallized structure 40. A width of the metallized structure 40 may be less than a width of the paddle 101, and a width of the die 20 may be less than the width of the metallized structure 40. This configuration allows the paddle 101 to extend out from edges of the metallized structure 40 and the metallized structure 40 to extend out from edges of the chip 20, thereby creating the wire bonding areas for the paddle 101 and the metallized structure 40 and thus enabling wire bonding between the die pad 101 and the chip 20, and between the chip 20 and the metallized structure 40. It should be noted that, as used herein, the term “width” refers to a dimension measured in a horizontal direction perpendicular to a direction in which a thickness of the die 20 is measured.

It should be noted that the paddle 101 and the metallized structure 40 are insulated from each other in accordance with the present application. That is, there is no electrical connection between the paddle 101 and the metallized structure 40. In one embodiment, the metallized structure 40 is attached to the paddle 101 by a die-attach process. For example, the metallized structure 40 may be attached to the paddle 101 using silver adhesive or an adhesive film.

FIG. 5 shows a schematic cross-sectional view of a metal metallized structure according to an embodiment of the present invention. In one embodiment, as shown in FIG. 5, the metallized structure 40 is a metal metallized structure including a silicon substrate 401 and a metal layer 402 arranged on the silicon substrate 401, the metal layer 402 covers a surface of the silicon substrate 401. The power pads 201 are electrically connected to the metal layer 402 by the first bonding wires 301 and the metal layer 402 is electrically connected to the corresponding pins 102 by the second bonding wires 302. It should be noted that since the metal layer 402 covers the entire surface of the silicon substrate 401, the power pads 201 on the die 20 may be connected to the respective nearest possible locations of the metal layer 402 by the first bonding wires 301. With this arrangement, the power pads 201, no matter where they are located, may be connected to the metallized structure 40, and the number of the power pads 201 connected to the metallized structure 40 is not limited. Moreover, the second bonding wire 302 can be connected at a position where the metallized structure 40 is close to the corresponding pin 102, thereby achieving a proximal connection between them.

For example, the metal layer 402 may consist of a single layer with one material layer or multiple layers with different material layers. As a non-limiting example, the metal layer 402 may include Al layer(s).

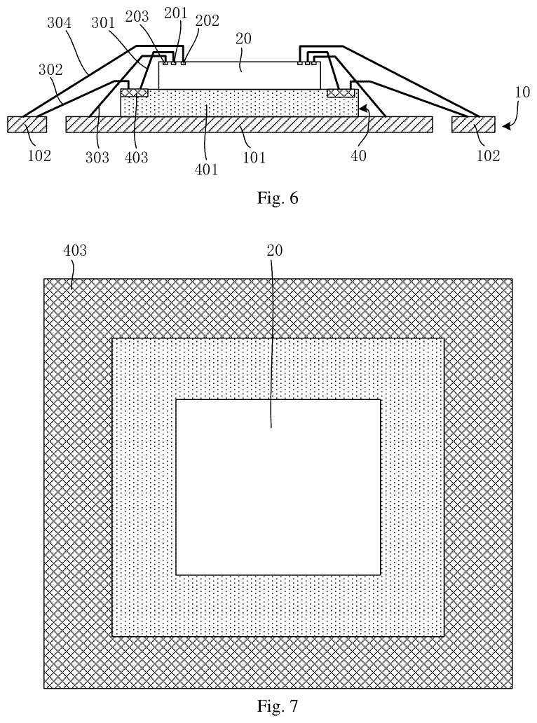

FIG. 6 is a cross-sectional view of the package structure of this embodiment, showing a redistribution layer (RDL) metallized structure therein. FIG. 7 shows a schematic assembly view of the die and the RDL metallized structure in this embodiment.

As shown in FIG. 6, in one embodiment, the metallized structure 40 is an RDL metallized structure and includes a silicon substrate 401 and an RDL 403 on the silicon substrate 401. A front side of the silicon substrate 401 is closer to the die 20. The RDL 403 is formed on the front side, and a backside of the silicon substrate 401 is attached to a surface of the paddle 101. The power pads 201 are electrically connected to the RDL 403 by the first bonding wires 301 and the RDL 403 is electrically connected to the corresponding pins 102 by the second bonding wires 302. Note that, according to the present application, the first 301 and second 302 bonding wires for the power pads 201 may have a different width than the third bonding wires 303 for the ground pads 203 and/or the fourth bonding wires for the signal input/output pads 202.

Referring to FIGS. 6 and 7, in one embodiment, the RDL 403 may extend on the front side of the silicon substrate 401 along the periphery thereof so as to surround the die 20. For example, the RDL 403 may be in the form of a wide annulus. This enables the power pads 201 on the front side of the die 20 to be more easily connected to the RDL 403 at low cost. For example, the RDL 403 may include a Cu layer, a Ni layer and an Au layer, which are stacked from the bottom upwards. This can enhance connection reliability between the bonding wires and the RDL 403. However, the invention is not limited to any particular material or structure of the RDL 403.

In some alternative embodiments, the RDL 403 may cover the front side of the silicon substrate 401 and include a Ni layer, a Pd layer and an Au layer which are sequentially stacked from the bottom upwards.

In some alternative embodiments, the metallized structure 40 may be a package substrate or the like.

In some embodiments, all the power pads 201 on the front side of the die 20 may be connected to the metallized structure 40 by respective first bonding wires 301. This can enhance ESD protection and power supply integrity of the package structure as much as possible. In some embodiments, if required, only some of the power pads 201 on the front side of the die 20 may be connected to the metallized structure 40.

In some embodiments, the pins 102 connected by the second bonding wires 302 are power pins VDD, and the number of second bonding wires 302 is smaller than that of first bonding wires 301. With this arrangement, external connection of the power pads 201 can be achieved in a manner of providing ESD protection and minimizing occupation of pin resources.

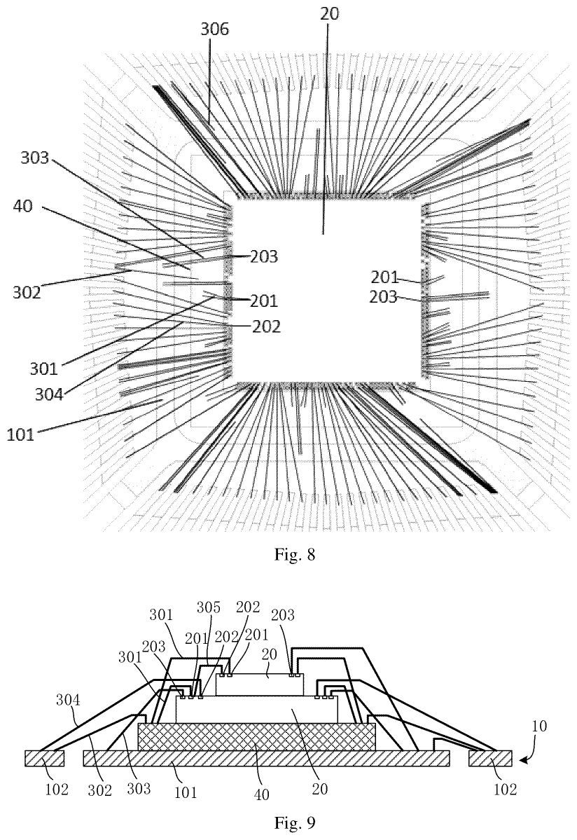

FIG. 8 is a front view of the package structure of this embodiment, showing the ground pads on the die which are connected to the paddle.

In some embodiments, referring to FIGS. 3 and 8, the paddle 101 is grounded. The ground pads 203 on the front side of the die 20 are all connected to the paddle 101 by third bonding wires 303. With this arrangement, the ground pads 203 can be externally connected to a ground (VSS) circuit to allow electrostatic charge to be effectively discharged, leading to improved ESD capabilities and performance of the package structure. The present invention is not limited to any particular number of externally connectable ground pads 203. It should be noted that the width of the paddle 101 is greater than the width of the metallized structure 40 and is greater than the width of the die 20, the ground pads 203 on the front side of the die 20 can be all connected to respective nearest possible locations of the paddle 101 and thus grounded through the paddle 101. With this arrangement, external connection of the ground pads 203 is not limited by the availability of pin resources, in particular in terms of the number and location of pins.

In one embodiment, all the ground pads 203 on the front side of the die 20 are connected to the paddle 101 by respective third bonding wires 303. However, the present invention is not so limited, if required, only some of the ground pads 203 on the front side of the die 20 may be connected to the paddle 101.

For example, referring to FIGS. 3 and 8, the paddle 101 may be connected by sixth bonding wires 306 to corresponding pins 102, which are grounded (the pins connected with sixth bonding wires 306 are referred to hereinafter as “ground pins” VSS). However, the present invention is not so limited, in some alternative embodiments, the paddle 101 may be grounded directly.

Referring to FIGS. 3, 4, 6 and 8, the signal input/output pads 202 on the front side of the die 20 are connected to corresponding ones of the pins 102 (the pins connected with fourth bonding wires 304 are signal input/output pins) by fourth bonding wires 304.

According to the present application, the bonding wires may be made of a material including, without limitation, Au, Ag, Cu and Al.

FIG. 9 is a cross-sectional view of the package structure of this embodiment, showing a plurality of dies stacked on the metallized structure.

In some embodiments, referring to FIG. 9, in the package structure, a plurality of dies 20 may be stacked on the metallized structure 40. For example, each die 20 may have a front side facing away from the metallized structure 40 and provided thereon with a plurality of power pads 201, the plurality of power pads 201 of each die 20 are connected to the metallized structure 40 by corresponding first bonding wires 301 and the metallized structure 40 is connected to the corresponding pins 102 by the second bonding wires 302.

For each die 20, all or some of the power pads 201 may be connected to the metallized structure 40, as required.

For example, referring to FIG. 9, on the front side of each die 20, there may also be a plurality of ground pads 203, all or some of which may be connected to the paddle 101 by corresponding third bonding wires 303. The paddle is grounded.

On the front side of each of the stacked dies 20, there may be a plurality of signal input/output pads 202 each connected to another die by a fifth bonding wire 305, or to a corresponding pin 102 by a fourth bonding wire 304.

In one embodiment, referring to FIG. 9, when the plurality of dies 20 are stacked, the front side of each die 20 comprises a plurality of signal input/output pads 202. The signal input/output pads 202 on the front side of the upper die may be connected to corresponding pads on the front side of the lower die by fifth bonding wires 305, while the signal input/output pads 202 on the front side of the lower die may be connected by fourth bonding wires 304 to corresponding pins 102 (the pins connected with fourth bonding wires 304 are referred to hereinafter as signal input/output pins). Alternatively, some of the signal input/output pads 202 on the front side of the upper die may be connected to corresponding pads on the front side of the lower die, while the remaining signal input/output pads 202 may be connected by fourth bonding wires 304 to corresponding pins 102 (the pins connected with fourth bonding wires 304 are referred to hereinafter as signal input/output pins). According to the present application, external connection of the signal input/output pads on the stacked dies may be appropriately designed in practical applications.

It should be noted that although FIG. 9 shows two dies 20 stacked on the metallized structure 40, the present invention is not so limited. More than two dies 20 may also be stacked on the metallized structure 40. To facilitate wire bonding, a width of the upper die is smaller than a width of a lower die.

In the present embodiment, there is provided a package structure including a lead frame, which includes a paddle and a plurality of pins arranged around the paddle. A die and a metallized structure are stacked on the paddle. On a front side of the die, there is a plurality of power pads which are electrically connected to the metallized structure by first bonding wires and the metallized structure is electrically connected to the corresponding pins by second bonding wires. With the presence of the metallized structure, the number of externally connectable power pads is not limited by the availability of pin resources, and the external connection of the power pads is not limited by their own location. Consequently, the power pads on the front side of the die can be all connected to the pins, allowing electrostatic charge to be preferentially discharged through a power supply (VDD) circuit. This imparts enhanced ESD protection and power supply integrity to the package structure, without retrofit of the die itself or the lead frame in terms of design, leading to increased compatibility. Further, when a plurality of dies may be stacked on the paddle, power pads on each die can be connected to the metallized structure by corresponding first bonding wires and the metallized structure can be connected to corresponding pin by second bonding wires. For example, in the case of two stacked dies, pin resources can be at least saved from being occupied by external connection of the power pads on one of the dies.

### Embodiment 2

In order to achieve enhanced ESD protection and reliability, package structures according to some embodiments incorporate a metallized structure 40 located above at least some dies 20.

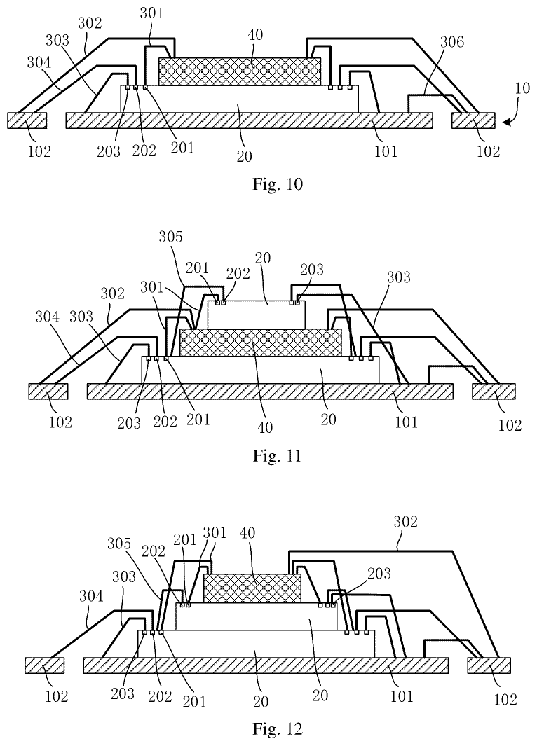

FIG. 10 is a cross-sectional view of a package structure according to an embodiment of the present invention, showing a metallized structure located over a die. Referring to FIG. 10, the package structure of this embodiment includes a lead frame 10, at least one die 20 and a metallized structure 40. The lead frame 10 includes a paddle 101 and a plurality of pins 102 arranged around the paddle 101. The paddle 101 is grounded to provide a ground plane. The die 20 is attached to the paddle 101 on top thereof so that a backside of the die 20 faces toward the paddle 101 and a front side thereof faces away from the paddle 101. There is a plurality of power pads 201 on the front side of the die 20, and the metallized structure 40 is arranged above the at least one die 20. The power pads 201 on the die 20 are connected to the metallized structure 40 by first bonding wires 301, and the metallized structure 40 is connected to corresponding pins 102 by second bonding wires 302.

It should be noted that in the package structure, the power pads 201 on the front side of the die 20 are electrically connected to the metallized structure 40 by the first bonding wires 301 and the metallized structure 40 is electrically connected to the corresponding pins 102 by the second bonding wires 302. With the presence of the metallized structure 40, the number of externally connectable power pads 201 is not limited by the availability of pin resources, and the external connection of the power pads 201 is not limited by their own location. Consequently, the power pads 201 on the front side of the die 20 can be all connected to the pins, allowing electrostatic charge to be preferentially discharged through a power supply (VDD) circuit. This imparts enhanced ESD protection and power supply integrity to the package structure, without retrofit of the die itself or of the lead frame in terms of design, leading to increased compatibility. In addition, with the paddle 101 serving as a ground plane, connecting the power pads 201 on the die 20 to the metallized structure 40 makes the metallized structure 40 act as a power plane. Thus, arranging the metallized structure 40 above the die 20 can increase the distance between the paddle 101, i.e., the ground (VSS) plane and the metallized structure 40, i.e., the power supply (VDD) plane, thereby increasing a creepage distance between the power supply plane and the ground plane and imparting improved reliability to the package structure and making it suitable for use in applications with a great VDD-VSS drop and in harsh environments such as those with high altitude and/or high humidity.

Additionally, arranging the metallized structure 40 above the die 20 allows the metallized structure 40 to have a smaller width than the underlying die 20, resulting in cost reductions.

Specifically, as required in practical applications, some or all of the power pads 201 on the front side of the die 20 may be connected to the metallized structure 40.

Referring to FIG. 10, on the front side of the die 20, there is also a plurality of signal input/output pads 202 which are connected to corresponding pins 102 (i.e., signal input/output pins) by fourth bonding wires 304. On the front side of the die 20, there may also be a plurality of ground pads 203 which may be connected to the paddle 101 by third bonding wires 303, and the paddle 101 is connected to the pins 102 (i.e., ground pins) by sixth bonding wires 306.

FIG. 11 is a cross-sectional view of the package structure of this embodiment, showing a metallized structure being interposed between multiple dies. FIG. 12 is a cross-sectional view of the package structure of this embodiment, showing a metallized structure being disposed above multiple dies.

Referring to FIGS. 11 and 12, the package structure may include a plurality of dies 20 stacked on the paddle 101, each of which has a backside facing toward the paddle 101 and a front side facing away from paddle 101. And a plurality of power pads 201 are provided on front side of each die. The metallized structure 40 may be located above at least some of the dies 20, and the power pads 201 on at least some of the dies 20 may be connected to the metallized structure 40 by first bonding wires 301.

For example, referring to FIGS. 11 and 12, the power pads 201 on the front side of each die 20 may be connected to the metallized structure 40 by corresponding first bonding wires 301.

In some embodiments, referring to FIG. 11, the metallized structure 40 may be interposed between multiple dies 20, for example, between two dies 20. As shown in FIG. 11, a lower die 20 has a greater width than an upper die 20. The upper die 20 is located over the metallized structure 40, and its width is less than a width of the metallized structure 40. The lower die 20 underlies the metallized structure 40, and its width is greater than the width of the metallized structure 40. The power pads 201 on the die 20 located over the metallized structure 40 are connected to the metallized structure 40 by corresponding downwardly-extending first bonding wires 301, and the power pads 201 on the die 20 underlying the metallized structure 40 are connected to the metallized structure 40 by corresponding upwardly-extending first bonding wires 301. The metallized structure 40 is connected to the corresponding pins 102 by the second bonding wires 302.

In some embodiments, referring to FIG. 12, the metallized structure 40 may be arranged above multiple dies 20. The multiple dies 20 are located between the metallized structure 40 and the paddle 101. Each die 20 has a smaller width than die 20 that underlies the specific die 20, and the topmost metallized structure 40 has a smaller width than the underlying dies. The power pads 201 on each die 20 are connected to the metallized structure 40 by corresponding upwardly-extending first bonding wires 301 and the metallized structure 40 is connected to the corresponding pins 102 by the second bonding wires 302.

It should be noted that each die 20 stacked above the paddle 101 may be a microcontroller unit (MCU), memory, sensing, power supply unit (PMU) or other die. In the case of a common VDD power supply domain being shared among the dies 20, the dies may be all stacked on the single paddle 101, with the power pads on each die 20 being connected to the metallized structure 40 on the paddle 101 by corresponding first bonding wires 301.

When the multiple dies 20 are stacked on the paddle 101, at least some dies may have the ground pads 203 on their front sides connected to the paddle 101 by third bonding wires 303, and external connection of the ground pads 203 may be appropriately configured, as required, in practical applications. In some embodiments, referring to FIGS. 11 and 12, the ground pads 203 on the front side of each die 20 may be connected to the paddle 101 by corresponding third bonding wires 303, and the number of ground pads 203 on each die 20 connected to the paddle 101 may be appropriately determined as required in practical applications. With this arrangement, external connection of the ground pads 203 is not limited by the availability of pin resources. In some alternative embodiments, the ground pads 203 on the front sides of some of the dies 20 may be connected to the paddle 101 by third bonding wires 303, while the ground pads 203 on the remaining ones may be wire bonded to corresponding pins 102.

When multiple dies 20 are stacked on the paddle 101, the signal input/output pads 202 on the front side of one die 20 may be connected to another die 20 by fifth bonding wires 305, or to corresponding pins 102 (i.e., signal input/output pins) by fourth bonding wires 304. Still alternatively, some of the signal input/output pads 202 on the front side of the die 20 may be connected to another die 20 by fifth bonding wires 305, while the remaining ones may be connected to corresponding pins 102 (i.e., signal input/output pins) by fourth bonding wires 304.

According to the present application, one or more flip-chip dies may also be added to the stack of the metallized structure 40 and the dies 20 (all of which are of the wire-bonded type).

According to the present application, the package structure may further include an encapsulant (not shown), which may encapsulate the die(s) 20, the metallized structure 40, the bonding wires and part of the lead frame 10. The encapsulant may encapsulate end portions of the pins 102 close to the paddle 101, with end portions of the pins 102 away from the paddle 101 remaining exposed. The encapsulant may cover a front side of the paddle 101 and part of a backside thereof. The remaining portion of the backside of the paddle 101 that is not covered by the encapsulant can facilitate heat dissipation from the die(s).

In the present embodiment, there is provided a package structure including a lead frame 10, which includes a paddle 101 and a plurality of pins 102 arranged around the paddle 101. At least one die 20 and a metallized structure 40 are stacked on the paddle 101, and on a front side of the die 20, there is a plurality of power pads 201 which are electrically connected to the metallized structure 40 by first bonding wires 301, and the metallized structure 40 is electrically connected to the corresponding pins 102 by second bonding wires 302. With the presence of the metallized structure 40, the number of externally connectable power pads 201 is not limited by the availability of pin resources, and the external connection of the power pads 201 is not limited by their own location. Consequently, multiple power pads 201 on the front side of the die 20, or even all of these power pads 201, can be connected to the pins 102, allowing electrostatic charge to be preferentially discharged through a power supply (VDD) circuit. This imparts enhanced ESD protection and power supply integrity to the package structure, without retrofit of the die itself or of the lead frame in terms of design, leading to increased compatibility. In addition, in the case of a plurality of dies being stacked on the paddle in the package structure, power pads on these dies can be all connected to the metallized structure by corresponding first bonding wires and the metallized structure is connected to the pins by first bonding wires. For example, in the case of two stacked dies, pin resources can be at least saved from being occupied by external connection of the power pads on one of the dies.

Additionally, on the front side of the die 20, there may also be a plurality of ground pads 203 connected to the paddle 101 by third bonding wires 303. With this arrangement, external connection of the ground pads 203 is not limited by the availability of pin resources, in particular in terms of the number and location of pins. Thus, external connection of the plurality of ground pads 203 can be achieved, thereby allowing electrostatic charge to be effectively discharged by the ground circuit, leading to improved ESD capabilities and performance of the package structure.

Further, the paddle 101 may be grounded, and the metallized structure 40 may be disposed above the die 20, the power pads 201 on the die 20 are connected to the metallized structure 40 by first bonding wires 301 and the metallized structure 40 is connected to the corresponding pins 102 by second bonding wires 302. With this arrangement, the paddle 101 serves a ground plane and the metallized structure 40 as a power plane. Arranging the metallized structure 40 above the die 20 increases the distance between the paddle 101, i.e., the ground (VSS) plane and the metallized structure 40, i.e., the power supply (VDD) plane, that is, a creepage distance between the ground plane and the power supply plane is increased, thereby imparting improved reliability to the package structure and making it suitable for use in applications with a great VDD-VSS drop and in harsh environments such as those with high altitude and/or high humidity. Furthermore, arranging the metallized structure 40 above the die 20 allows the metallized structure 40 to have a smaller width than the underlying die 20, resulting in cost reductions.

### Embodiment 3

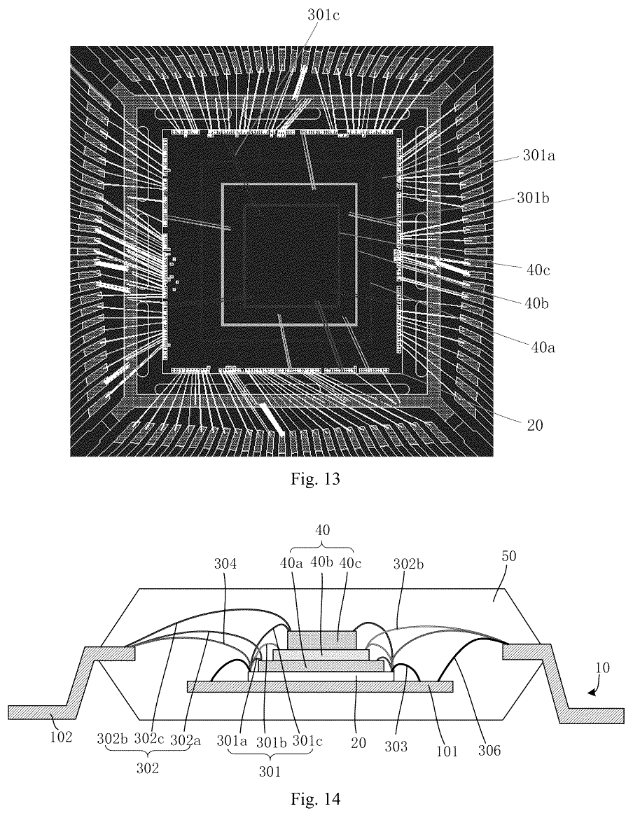

There is also provided herein a package structure, which addresses varying power demands of multiple power distribution networks (PDNs). Referring to FIGS. 13 to 17, the package structure includes a lead frame 10, at least one die 20 and a plurality of metallized structures 40. The lead frame 10 includes a paddle 101 and a plurality of pins 102 arranged around the paddle 101. The at least one die 20 includes multiple power pads which belong to respective different PDNs. The plurality of metallized structures 40 and the at least one die 20 are stacked on the paddle 101, and each metallized structure 40 corresponds to a PDN. The plurality of power pads of each PDN are electrically connected to the corresponding metallized structure 40 by first bonding wires 301 and the metallized structure 40 is electrically connected to the corresponding pins 102 by the second bonding wires 302.

In one embodiment, as shown in FIGS. 13 and 14, the package structure includes one die 20, and there are multiple power pads on a front side of the die 20, the multiple power pads are arranged in peripheral regions of the front side of the die and belong to different PDNs. According to the present application, the front side of the die 20 provided with the pads faces away from the paddle 101, and a backside of the die 20 faces toward the paddle 101.

For example, the die 20 may be used to handle power demands of three PDNs. In this case, the package structure includes three metallized structures 40. A plurality of power pads of a first PDN VDD1 are electrically connected to a first metallized structure 40a by a first portion of first bonding wires 301a and the first metallized structure 40a is electrically connected to the corresponding pins 102 by a first portion of second bonding wires 302a. A plurality of power pads of a second PDN VDD2 are electrically connected to a second metallized structure 40b by a second portion of first bonding wires 301b and the second metallized structure 40b is electrically connected to the corresponding pins 102 by a second portion of second bonding wires 302b. A plurality of power pads of a third PDN VDD3 are electrically connected to a third metallized structures 40c by a third portion of first bonding wires 301c and the third metallized structure 40c is electrically connected to the corresponding pins 102 by a third portion of second bonding wires 302c.

It should be noted that there may also be two or more than three metallized structures 40 in the package structure, and the number of metallized structures 40 may depend on the number of PDNs, the number of power pads to be externally connected and other factors.

In this embodiment, the pins 102 connected by the second bonding wires 302 are power pins of the package structure, and the number of second bonding wires 302 is smaller than the number of first bonding wires 301. With this arrangement, external connection of the power pads can be achieved in a manner of providing ESD protection and minimizing occupation of pin resources.

In the package structure of this embodiment, each metallized structure 40 corresponds to a respective PDN, and multiple PDNs may be handled by a single or multiple dies. Therefore, there are as many metallized structures 40 as there are PDNs. In alternative embodiments, if required, each PDN may correspond to two or more metallized structures 40. Accordingly, a plurality of power pads on a single die 20 for the specific PDN may be connected to the two or more metallized structure 40. Alternatively, power pads on different dies 20 for the specific PDN may be connected to different metallized structures 40. In this embodiment, one or more dies 20 comprises a power demand of multiple PDNs. Power pads on each die belong to distinct multiple PDNs.

In this embodiment, different PDNs may correspond to different power supply voltages, but the present invention is not so limited. By providing a stacked metallized structure 40, at least one metallized structure 40 may be provided for each PDN, thereby enabling support for multiple power supply voltages. For example, each metallized structure 40 may be independently configured, based on different requirements of the PDNs, different metallized structures 40 may be provided for different PDNs. In this way, desirable impedance properties for different PDNs may be provided, which help optimize impedance performance of the PDNs and create optimal current paths. More specifically, the area, material, wire width and the like of each metallized structure 40 may be configured according to the number of power pads to be connected to the specific metallized structure 40 so as to achieve impedance properties configuration for the corresponding PDN. For example, the area of the metallized structure 40 may be expanded to accommodate the connection of more power pads. In the example of FIG. 14, the first metallized structure 40a may have a greater area than the second metallized structure 40b because more power pads are to be connected to the first metallized structure 40a than the second metallized structure 40b.

In this embodiment, the metallized structures 40 may be sequentially stacked one on another so that each metallized structure 40 has a greater width than metallized structure 40 underlying the specific metallized structure 40. In this way, each metallized structure 40 has exposed wire bonding regions to facilitate connection of power pads on the front side of the die with the metallized structure 40 by the first bonding wires 301. In the example of FIG. 14, the first metallized structure 40a, the second metallized structure 40b and the third metallized structure 40c may be stacked on the paddle 101 sequentially from the bottom upwards. Accordingly, the first metallized structure 40a may have a greater width than the second metallized structure 40b, the second metallized structure 40 may have a greater width than the third metallized structure 40c. Thus, the first metallized structure 40a may have wire bonding regions extending laterally beyond the extent of the second metallized structure 40b, the second metallized structure 40b may have wire bonding regions extending laterally beyond the extent of the third metallized structure 40c. Here, the width is measured horizontally as viewed in the orientation of FIG. 14.

In this embodiment, as shown in FIGS. 13 and 14, the backside of the die 20 is attached to the paddle 101, and the metallized structures 40 are sequentially stacked on a central portion of the die 20 on the front side thereof. That is, the die 20 is stacked blow the plurality of metallized structures 40. Accordingly, the die 20 may have a greater width than the first metallized structure 40a located above, with the pads in the peripheral regions of its front side remaining exposed.

It should be noted that, according to the present invention, stacking the metallized structures 40 in such a flexible manner can not only address the varying power demands of the PDNs, but can also result in increased spatial integration and help optimize die area utilization.

In some embodiments, all the power pads on the front side of the die 20 may be connected to the metallized structures 40 by respective first bonding wires 301. This can enhance the ESD protection performance and power supply integrity of the package structure as much as possible. In some embodiments, if required, only some of the power pads on the front side of the die 20 may be connected to the metallized structures 40.

With continued reference to FIG. 14, on the front side of the die 20, there may also be a plurality of signal input/output pads (not shown), which are electrically connected to corresponding pins 102 by fourth bonding wires 304.

Referring to FIG. 14, on the front side of the die 20, there may also be a plurality of ground pads (not shown) which are connected to the paddle 101 by third bonding wires 303 and the paddle 101 is connected to the corresponding pins 102 (i.e., ground pins) by sixth bonding wires 306. With this arrangement, external connection of the ground pads can be achieved, without the number of externally connectable ground pads being limited. Thus, electrostatic charge can be effectively discharged through a ground circuit, facilitating discharge of electrostatic charge from the package structure and enhancing its ESD protection performance. It should be noted that the paddle 101 has a greater width than all the metallized structures 40 and the die 20. Thus, all the ground pads on the front side of the die 20 can be connected to the respective nearest possible locations of the paddle 101 and thereby grounded via the paddle 101. In this way, external connection of the ground pads is not limited by the availability of pin resources, in particular in terms of the number and location of pins.

In some embodiments, all the ground pads on the front side of the die 20 may be connected to the paddle 101 by respective third bonding wires 303. This can enhance ESD protection performance and power supply integrity of the package structure as much as possible. In some embodiments, if required, only some of the ground pads on the front side of the die 20 may be connected to the paddle 101.

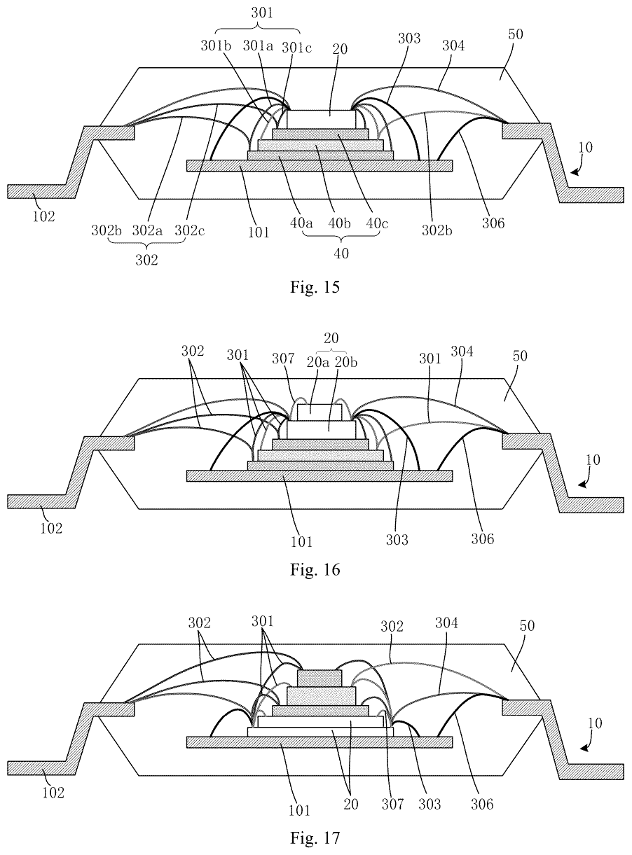

In one embodiment, as shown in FIG. 15, the multiple metallized structures 40 are sequentially stacked on the paddle 101, and the package structure includes a single die 20 stacked above the multiple metallized structures 40, i.e., on the topmost third metallized structure 40c. In this case, the die 20 has a smaller width than the underlying third metallized structure 40c.

In some embodiments, as shown in FIGS. 16 and 17, the package structure may include multiple dies 20, at least one die has multiple power pads belonging to different PDNs. That is, at least one die is intended to address power demands of multiple PDNs.

In one embodiment, each die 20 in the package structure may have a plurality of power pads electrically connected to a respective metallized structure 40 by respective first bonding wires 301. For example, the power pads on two dies (e.g., a first die 20a and a second die 20b) are electrically connected by respective first bonding wires 301 respectively to the first metallized structure 40a, the second metallized structure 40b and the third metallized structure 40c.

In one embodiment, the package structure includes two dies 20, namely, a first die 20a and a second die 20b. At least some power pads on the first die 20a and some power pads on the second die 20b belong to a single PDN. For example, for the power pads of the same PDN, the at least some of the power pads on the first die 20a that belong to the PDN are electrically connected to the second die 20b, more precisely to the power pads on the second die 20b that belong to the same PDN, by corresponding seventh bonding wires 307. Moreover, the power pads on the second die 20b that belong to the PDN are in turn connected to a respective metallized structure 40 by corresponding first bonding wires 301.

In some alternative embodiments, the package structure includes a plurality of dies 20 each with a plurality of power pads on its front side, which belong to a single PDN. The PDN(s) that the power pads on at least some of the dies 20 belong to differ(s) from the PDN(s) that the power pads on the remaining one(s) of the dies 20 belong to. That is, each die in the package structure is intended to address a power demand of a single PDN, and different dies comprise power demands of different PDNs, thus the plurality of dies are intended to address power demands of multiple PDNs. In these embodiments, the power pads on the dies 20 may be all electrically connected to corresponding metallized structures 40 by corresponding first bonding wires 301.

For example, on the front side of each of the first die 20a and the second die 20 b, there may be a plurality of ground pads (not shown) which are connected to the paddle 101 by corresponding third bonding wires 303 and the paddle 101 is connected to the corresponding pins 102 by sixth bonding wires 306.

Each of the first die 20a and the second die 20 b may include a plurality of signal input/output pads each connected to another one of the dies by a fifth bonding wire, or directly to a corresponding pin 102 by a fourth bonding wire 304. In some embodiments, some of the signal input/output pads on the first die 20a are connected to corresponding pins 102 by fourth bonding wires 304, and the remaining signal input/output pads on the first die 20a may be connected to the second die 20b by fifth bonding wires. The signal input/output pads on the second die 20b may be all connected to corresponding pins 102 by fourth bonding wires 304. In an alternative embodiment, the signal input/output pads on the first die 20a and the second die 20 b are all connected to corresponding pins 102 by fourth bonding wires 304.

In one embodiment, referring to FIG. 16, the plurality of dies 20 are disposed above the plurality of metallized structures 40 so that the metallized structures 40 are situated between a lowermost one of the dies and the paddle 101. In one embodiment, as shown in FIG. 17, the dies 20 are sequentially stacked on the paddle 101, and the plurality of metallized structures 40 are stacked on a topmost one of the dies. In some embodiments, the dies 20 and the metallized structures 40 are mixed together. As a non-limiting example, the die 20 may be disposed between two metallized structures 40, or between a lowermost one of the metallized structures and the paddle 101, or above a topmost one of the metallized structures.

It should be noted that in the stack of the dies 20 and the metallized structures 40, each metallized structure 40 or die 20 has a smaller width than underlying metallized structure 40 or die 20, ensuring that the pads in the peripheral regions of the front sides of the dies 20 and peripheral regions of the metallized structures 40 are exposed to enable electrical connection of the dies 20 and metallized structures 40 by wire bonding.

For example, the numbers, materials and areas of metal layers 402 in the metallized structures 40 may be configured depend on required impedance properties for the respective PDNs.

It should be noted that when a metallized structure 40 is disposed on another metallized structure, an insulating layer may be disposed between them to electrically insulate them from each other. The insulating layer may include, without limitation, an insulating coating (e.g., polyimide or the like), a dielectric film (e.g., aluminum oxide or the like), a dielectric layer or the like. The die surface may also be attached to adjacent metallized structure surface by an insulating material, and electrical connections are established between the die 20 and the metallized structure 40 by bonding wires.

Referring to FIGS. 14 to 18, the die(s) 20, the paddle 101 and the bonding wires may be encapsulated in an encapsulant 50. The encapsulant 50 may also encapsulate a portion of each pin 102, with the remaining portion thereof remaining exposed. For example, the encapsulant 50 may be made of a material including, without limitation, epoxy-based material.

In some embodiments, the package structure is a low-profile quad flat package. In this case, referring to FIGS. 14 to 17, the encapsulant 50 may encapsulate an end portion of each pin 102 proximal to the paddle 101, with the remaining portion of thereof away from the paddle 101 exposed. That is, each pin 102 may laterally extend out of the encapsulant 50 away from the paddle 101.

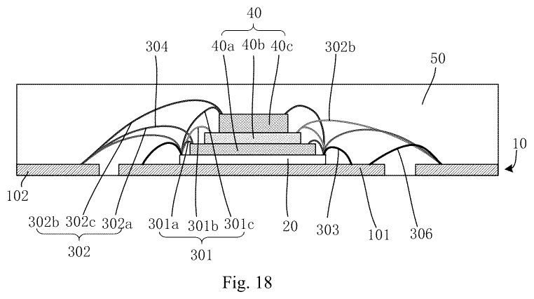

In some embodiments, the package structure is a quad flat no-lead (QFN) package. FIG. 18 shows a schematic cross-sectional view of the QFN package according to an embodiment of the present invention. Referring to FIG. 18, the encapsulant 50 may encapsulate an upper portion of each pin 102, with the remaining lower portion thereof being exposed. In this case, the pins 102 may not laterally extend out of the encapsulant 50.

In the present embodiment, there is provided a package structure including a lead frame 10, at least one die 20 and a plurality of metallized structures 40. The lead frame 10 includes a paddle 101 and a plurality of pins 102 arranged around the paddle 101. The at least one die 20 has multiple power pads belonging to respective different PDNs. The plurality of metallized structures 40 and the at least one die 20 are stacked on the paddle 101, with each metallized structure 40 corresponding to a respective PDN. The plurality of power pads of each PDN are electrically connected to the respective metallized structure 40 by first bonding wires 301 and the metallized structure 40 is electrically connected to the corresponding pins 102 by second bonding wires 302. The PDNs may have different power demands, and the presence of the metallized structures 40 can address these demands. Moreover, the metallized structures may be configured to provide desirable impedance properties for the demands of the PDNs, thereby helping optimize impedance performance of the PDNs and create optimal current paths. These can result in higher power transmission efficiency and more stable circuit performance. Additionally, the number of externally connectable power pads for any PDN is not limited by the availability of pin resources, meaning that such external connection does not take up too much pin resources. Further, external connection of power pads is not limited by their own location. Multiple power pads on a front side of the die, or even all of them, can be connected to the pins 102, allowing electrostatic charge to be preferentially discharged through a power supply circuit. This imparts enhanced ESD protection and power supply integrity to the package structure, without retrofit of the die itself or of the lead frame in terms of design, leading to increased compatibility. Furthermore, through providing each PDN with a respective metallized structure (different PDNs are connected to different metallized structures), voltage drops and ground noise of multiple PDNs can be effectively reduced, resulting in improved circuit performance.

Optionally, the package structure may comprise a single metallized structure attached to the paddle, wherein the die is attached to the metallized structure, and wherein the die comprises a backside facing toward the paddle and a front side facing away from the paddle.

Optionally, the package structure may comprise a single metallized structure disposed above at least one die, wherein the die is attached above the paddle and comprises a backside facing toward the paddle and a front side facing away from the paddle.

Optionally, on a direction perpendicular to a thickness direction of the die, a width of the metallized structure is greater than a width of the die, and wherein a width of the paddle is greater width than a width of the metallized structure.

Optionally, a plurality of ground pads are provided on the front side of the die, wherein the plurality of ground pads are connected to the paddle by third bonding wires, and wherein the paddle is grounded.

Optionally, a plurality of signal input/output pads are provided on the front side of the die, and wherein the plurality of signal input/output pads are connected to corresponding pins by fourth bonding wires.

Optionally, the package structure may comprise a plurality of dies stacked on the metallized structure, each die comprises a front side facing away from the metallized structure, and wherein the plurality of power pads on the front side of each die are connected to the metallized structure by corresponding first bonding wires.

Optionally, the metallized structure may comprise a silicon substrate and a metal layer disposed on the silicon substrate, the metal layer covers a surface of the silicon substrate, wherein each power pad is electrically connected to the metal layer by the first bonding wire and the metal layer is connected to corresponding pin by the second bonding wire.

Optionally, the metallized structure may comprise a silicon substrate and a redistribution layer (RDL) on the silicon substrate, wherein each power pad is electrically connected to the RDL by the first bonding wire and the RDL is electrically connected to corresponding pin by the second bonding wire.

Optionally, the metallized structure may comprise a silicon substrate and an RDL on the silicon substrate, wherein each power pad is electrically connected to the RDL by the first bonding wire and the RDL is electrically connected to the corresponding pin by the second bonding wire, wherein a front side of the silicon substrate is closer to the die, and wherein the RDL is disposed in a peripheral region of the front side of the silicon substrate and surrounds the die.

Optionally, the metallized structure may be a package substrate.

Optionally, the pins may be power a pin, wherein the number of second bonding wires is smaller than the number of first bonding wires.

Optionally, the package structure may comprise a plurality of dies stacked on the paddle, wherein each die comprises a backside facing toward the paddle and a front side facing away from the paddle, wherein a plurality of power pads are provided on a front side of each die, and wherein the power pads on at least some of the plurality of dies are connected to the metallized structure by corresponding first bonding wires.

Optionally, each power pad on the front side of the die is connected to the metallized structure by corresponding first bonding wire.

Optionally, the package structure may comprise a plurality of metallized structures, each power pad on the front side of the die is connected to the metallized structure by corresponding first bonding wire.

Optionally, the die may be associated with a plurality of PDNs, and the number of the metallized structures is equal to the number of the PDNs.

Optionally, the package structure may comprise a plurality of dies, wherein: the plurality of power pads on the front side of at least one die belongs to the different PDNs; or the plurality of power pads on the front side of each die belongs to one PDN, and the power pads on at least some of the dies correspond to the PDN that is different from a PDN that the power pads on the remaining dies correspond to.

Optionally, the package structure may comprise a first die and a second die, wherein at least some of the power pads on the first die and at least some of the power pads on the second die belong to a single PDN, wherein for the power pads that belong to the single PDN, at least some of the power pads on the first die that belong to the PDN are electrically connected to the power pads on the second die that belong to the PDN by seventh bonding wires, and wherein the power pads on the second die that belong to the PDN are connected to the respective metallized structure by corresponding first bonding wires.

Optionally, the plurality of power pads of each die may be electrically connected to the metallized structures by corresponding first bonding wires.

Optionally, wherein: the at least one die is stacked above or below the plurality of metallized structures; or the at least one die and the plurality of metallized structures are arranged alternately, and wherein a width of the metallized structure or the die located above is smaller than a width of an underlying metallized structure or die.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A package structure, comprising:
a lead frame comprising a paddle and a plurality of pins arranged around the paddle;
at least one metallized structure disposed above the paddle; and
at least one die disposed above the paddle, wherein a plurality of power pads are provided on a front side of the die,
wherein the plurality of power pads are connected to the metallized structure by first bonding wires, and wherein the metallized structure is connected to corresponding pins by second bonding wires.

2. The package structure of claim 1, comprising a single metallized structure attached to the paddle, wherein the die is attached to the metallized structure, and wherein the die comprises a backside facing toward the paddle and a front side facing away from the paddle.

3. The package structure of claim 1, comprising a single metallized structure disposed above at least one die, wherein the die is attached above the paddle and comprises a backside facing toward the paddle and a front side facing away from the paddle.

4. The package structure of claim 2, wherein on a direction perpendicular to a thickness direction of the die, a width of the metallized structure is greater than a width of the die, and wherein a width of the paddle is greater width than a width of the metallized structure.

5. The package structure of claim 1, wherein a plurality of ground pads are provided on the front side of the die, wherein the plurality of ground pads are connected to the paddle by third bonding wires, and wherein the paddle is grounded.

6. The package structure of claim 1, wherein a plurality of signal input/output pads are provided on the front side of the die, and wherein the plurality of signal input/output pads are connected to corresponding pins by fourth bonding wires.

7. The package structure of claim 2, comprising a plurality of dies stacked on the metallized structure, wherein each die comprises a front side facing away from the metallized structure, and wherein the plurality of power pads on the front side of each die are connected to the metallized structure by corresponding first bonding wires.

8. The package structure of claim 1, wherein the metallized structure comprises a silicon substrate and a metal layer disposed over the silicon substrate, wherein the metal layer covers a surface of the silicon substrate, wherein each power pad is electrically connected to the metal layer by the first bonding wire and the metal layer is connected to corresponding pin by the second bonding wire.

9. The package structure of claim 1, wherein the metallized structure comprises a silicon substrate and a redistribution layer (RDL) on the silicon substrate, wherein each power pad is electrically connected to the RDL by the first bonding wire and the RDL is electrically connected to corresponding pin by the second bonding wire.

10. The package structure of claim 2, wherein the metallized structure comprises a silicon substrate and an RDL on the silicon substrate, wherein each power pad is electrically connected to the RDL by the first bonding wire and the RDL is electrically connected to the corresponding pin by the second bonding wire, wherein a front side of the silicon substrate is closer to the die, and wherein the RDL is disposed in a peripheral region of the front side of the silicon substrate and surrounds the die.

11. The package structure of claim 1, wherein the metallized structure is a package substrate.

12. The package structure of claim 1, wherein the corresponding pin is a power pin, and wherein a number of the second bonding wires is smaller than a number of the first bonding wires.

13. The package structure of claim 3, comprising a plurality of dies stacked on the paddle, wherein each die comprises a backside facing toward the paddle and a front side facing away from the paddle, wherein a plurality of power pads are provided on a front side of each die, and wherein the power pads on at least some of the plurality of dies are connected to the metallized structure by corresponding first bonding wires.

14. The package structure of claim 13, wherein each power pad on the front side of the die is connected to the metallized structure by corresponding first bonding wire.

15. The package structure of claim 1, comprising a plurality of metallized structures, wherein the plurality of power pads belong to different power distribution networks (PDNs), wherein each metallized structure corresponds to a respective PDN, wherein for each PDN, the plurality of power pads are electrically connected to respective metallized structure by corresponding first bonding wires and the metallized structure is electrically connected to corresponding pins by corresponding second bonding wires.

16. The package structure of claim 15, wherein the die is associated with a plurality of PDNs, and wherein a number of the metallized structures is equal to a number of the PDNs.

17. The package structure of claim 15, comprising a plurality of dies, wherein: the plurality of power pads on the front side of at least one die belongs to the different PDNs; or the plurality of power pads on the front side of each die belongs to one PDN, and the power pads on at least some of the dies correspond to the PDN that is different from a PDN that the power pads on the remaining dies correspond to.

18. The package structure of claim 15, comprising a first die and a second die, wherein at least some of the power pads on the first die and at least some of the power pads on the second die belong to a single PDN, wherein for the power pads that belong to the single PDN, at least some of the power pads on the first die that belong to the PDN are electrically connected to the power pads on the second die that belong to the PDN by seventh bonding wires, and wherein the power pads on the second die that belong to the PDN are connected to the respective metallized structure by corresponding first bonding wires.

19. The package structure of claim 15, wherein the plurality of power pads of each die are electrically connected to respective metallized structures by corresponding first bonding wires.

20. The package structure of claim 15, wherein: the at least one die is stacked above or below the plurality of metallized structures; or the at least one die and the plurality of metallized structures are arranged alternately, and wherein a width of the metallized structure or the die located above is smaller than a width of an underlying metallized structure or die.
